(19) United States
(12) Patent Application Publication
(10) Pub. No.: US 2022/0076929 A1
(43) Pub. Date: Mar. 10, 2022

(54) SUBSTRATE TREATING APPARATUS AND COVER RING THEREOF

(71) Applicant: SEMES CO., LTD., Chungcheongnam-do (KR)

(72) Inventors: SUNIL KIM, Cheonan-si (KR); SANG-KEE LEE, Cheonan-si (KR)

(21) Appl. No.: 17/458,872

(22) Filed: Aug. 27, 2021

(30) Foreign Application Priority Data
Sep. 8, 2020 (KR) 10-2020-0114922

(51) Int. Cl. H01J 37/32

(52) U.S. Cl. CPC H01J 37/32642; H01J 37/32009; H01J 37/32715; H01J 37/32467; H01J 37/3244

(57) ABSTRACT

Disclosed is a substrate treating apparatus. The substrate treating apparatus includes a process chamber that provides a treatment space in an interior thereof, a support unit that supports a substrate in the treatment space, a gas supply unit that supplies a process gas into the treatment space, and a plasma source that generates plasma from the process gas, the support unit includes a support plate, on which the substrate is positioned, and an edge ring assembly that surrounds the substrate supported on the support plate, and that forms the plasma in the substrate, and the edge ring assembly includes a focusing ring formed of a first material, and that forms distribution of the plasma in the substrate, and a cover ring provided in an area of the substrate, and including a reinforced surface layer provided by injecting a network modifier into an empty site of the network structure.

### CROSS-REFERENCE TO RELATED APPLICATIONS

A claim for priority under 35 U.S.C. § 119 is made to Korean Patent Application No. 10-2020-0114922 filed on Sep. 8, 2020, in the Korean Intellectual Property Office, the entire contents of which are hereby incorporated by reference.

### BACKGROUND

Embodiments of the inventive concept described herein relate to a substrate treating apparatus, and more particularly, to an apparatus for treating a substrate by using plasma, and a cover ring provided for an edge ring assembly that restricts plasma to an upper area of a substrate.

Plasma may be used for a substrate treating process. For example, plasma may be used for an etching, deposition, or dry cleaning process. Plasma is generated by a very high temperature, a strong electric field, or a radio frequency (RF) electromagnetic field, and the plasma refers to an ionized gaseous state including ions, electrons, and radicals. A dry cleaning, ashing, or wearing process using plasma is performed as ions or radical particles included in the plasma collide with a substrate.

The substrate treating apparatus using the plasma may include a chamber, a substrate support unit, and a plasma source. The substrate support unit may include an edge ring assembly disposed to surround the substrate such that the plasma faces the substrate. The edge ring assembly, for example, may include a configuration including a quartz material. Although the configuration (for example, the cover ring) manufactured of the quartz material causes a small amount of process by-products in an etching process equipment and hardly influences a process, it has a low anti-plasma property, has a short component exchange period due to generation of particles, and causes local etching as the plasma is concentrated in a defective portion of the surface of the quartz, and thus a life span of the equipment may be shortened.

The configuration of the quartz material may be rapidly corroded as it reacts with a fluorine gas in a plasma environment and is sublimated after generating SiF₄ having a low sublimation point, and may be worn by the plasma. When the quartz is etched in the plasma environment, a chamber component located at a lower portion of the edge ring assembly is exposed to the plasma, and the life span of the chamber component may decrease and an exchange period of the chamber component may be shortened. Furthermore, the worn edge ring assembly may make distribution of the plasma input to the substrate uneven. The uneven distribution of the plasma may cause the substrate not to be uniformly treated.

### SUMMARY

Embodiments of the inventive concept provide a cover ring provided for an edge ring assembly that may uniformly treat a substrate and form plasma distribution to increase a substrate treating efficiency, and a substrate treating apparatus including the same.

Embodiments of the inventive concept also may provide a cover ring provided for an edge ring assembly that has a high ante-plasma performance, hardly generates particles, and may increase a component exchange period, and a substrate treating apparatus including the same.

Embodiments of the inventive concept also may provide a method for manufacturing a quartz component having an improved anti-plasma property, which is exposed to plasma including fluorine, by which production costs may be reduced as the quartz component is manufactured in a relatively low temperature condition.

Embodiments of the inventive concept also provide a cover ring provided for an edge ring assembly, a surface of which is uniformly reinforced for a wide surface area, and a substrate treating apparatus including the same.

The aspect of the inventive concept is not limited thereto, and other unmentioned aspects of the present invention may be clearly appreciated by those skilled in the art from the following descriptions.

The inventive concept provides a substrate treating apparatus. The substrate treating apparatus includes a process chamber that provides a treatment space in an interior thereof, a support unit that supports a substrate in the treatment space, a gas supply unit that supplies a process gas into the treatment space, and a plasma source that generates plasma from the process gas, the support unit includes a support plate, on which the substrate is positioned, and an edge ring assembly that surrounds the substrate supported on the support plate, and that forms the plasma in the substrate, and the edge ring assembly includes a focusing ring formed of a first material, and that forms distribution of the plasma in the substrate, and a cover ring provided in an area of the substrate, which is on an outer side of the focusing ring, formed of a second material having a network structure, and including a reinforced surface layer provided by injecting a network modifier into an empty site of the network structure.

According to an embodiment, the first material may be a conductive material, and the second material may be a material having an insulating performance that is higher than that of the first material.

According to an embodiment, the first material may be silicon carbide (SiC), and the second material may be quartz having an amorphous network structure.

According to an embodiment, an ion radius of the network modifier may be larger than that of Si4+.

According to an embodiment, the network modifier may be any one or more of Na⁺, K⁺, Ca²⁺, or Mg²⁺.

According to an embodiment, the reinforced surface layer may have a thickness of 10 μm to 500 μm.

According to an embodiment, the edge ring assembly may further include an inner cover ring provided between the cover ring and the focusing ring, and located above an outer area of the focusing ring, and the inner cover ring may be formed of a third material, in which SiO₂ and Al₂O₃ are mixed at a first ratio.

According to an embodiment, the inner cover ring may include 96.0 to 99.5 wt % of SiO₂ and 0.5 to 4.0 wt % of Al₂O₃.

According to an embodiment, the process gas may be a gas containing fluorine.

The inventive concept provides a cover ring of an edge ring assembly that surrounds a substrate and forms plasma in the substrate in an apparatus for treating the substrate by the plasma. The cover ring may include a reinforced surface layer having an inner diameter that is larger than a diameter of the substrate to be spaced apart from the substrate by a specific distance, formed of a material including a network structure, and provided by injecting a network modifier into an empty site of the network structure.

According to an embodiment, a material of the cover ring may be quartz having an amorphous network structure.

According to an embodiment, an ion radius of the network modifier may be larger than that of Si⁴⁺.

According to an embodiment, the network modifier may be any one or more of Na⁺, K⁺, Ca²⁺, or Mg²⁺.

According to an embodiment, the reinforced surface layer may have a thickness of 10 μm to 500 μm.

According to an embodiment, a process gas for forming the plasma may be a fluorine containing gas, and the reinforced surface layer may be exposed to fluorine radicals excited from the process gas.

The inventive concept provides a method for manufacturing a cover ring of an edge ring assembly that surrounds a substrate and forms plasma in the substrate in an apparatus for treating the substrate by the plasma. The method may include preparing a salt bath including a network modifier, an ion radius of which is larger than that of Si4+, and immersing the cover ring, a shape of which is machined with a material including a network structure, in the salt bath at a first temperature.

According to an embodiment, the first temperature may be a room temperature.

According to an embodiment, the salt bath may be provided with a water solution including CaCl₂), KCL, NaCl, or MgCl₂.

A method for manufacturing a cover ring of an edge ring assembly that surrounds a substrate and forms plasma in the substrate in an apparatus for treating the substrate by the plasma according to another aspect of the inventive concept includes preparing a paste material including a network modifier, an ion radius of which is larger than that of Si⁴⁺, and bringing a surface of the cover ring, a shape of which is machined with a material including a network structure, and the paste material into reaction with each other at a second temperature that is a temperature of a fusion point of the paste material or more.

According to an embodiment, the paste material may include one or more of CaCl₂), KCl, NaCl, or MgCl₂.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view illustrating a substrate treating apparatus according to an embodiment of the inventive concept;

FIG. 2 is an enlarged view of portion “A” of FIG. 1, and is a cross-sectional view of an edge ring assembly that constitutes the substrate treating apparatus according to the embodiment of the inventive concept;

FIG. 3 schematically illustrates a bonding structure of molecules between a reinforced surface layer 247b and a material layer 247a of a cover ring 247 of FIG. 2;

FIG. 4 is a view illustrating a substrate treating apparatus according to another embodiment of the inventive concept.

FIG. 5 is an enlarged view of portion “B” of FIG. 4, and is a cross-sectional view of an edge ring assembly that constitutes the substrate treating apparatus according to another embodiment of the inventive concept;

FIG. 6 is a flowchart illustrating a wetting type ion reinforcing method using a quartz material according to an embodiment of the inventive concept; and

FIG. 7 is a flowchart illustrating a drying type ion reinforcing method using a quartz material according to another embodiment of the inventive concept.

### DETAILED DESCRIPTION

Hereinafter, exemplary embodiments of the inventive concept will be described in more detail with reference to the accompanying drawings. The embodiments of the inventive may be modified in various forms, and the scope of the inventive concept should not be construed to be limited to the following embodiments. The embodiments of the inventive concept are provided to describe the inventive concept for an ordinary person skilled in the art more completely. Accordingly, the shapes of the components of the drawings are exaggerated to emphasize clearer description thereof.

In the embodiment of the inventive concept, a substrate treating apparatus for treating a substrate by generating plasma in an inductively coupled plasma (ICP) scheme will be described. However, the inventive concept is not limited thereto, and may be applied to various kinds of apparatuses that treat a substrate by using plasma, for example, by using a conductively coupled plasma (CCP) scheme or a remote plasma scheme.

Furthermore, in an embodiment of the inventive concept, an electrostatic chuck will be described as an example of a support unit. However, the inventive concept is not limited thereto and the support unit may support a substrate through mechanical clamping or by using vacuum.

The substrate treating apparatus according to the embodiment of the inventive concept includes an edge ring assembly having an excellent anti-plasma property (anti-etching property). The edge ring assembly includes a cover ring having an anti-etching property and configured to surround a substrate while being spaced apart from the substrate, and a focusing ring having an anti-etching property and provided at an inner side portion of the cover ring to form plasma distribution in the substrate. Furthermore, an edge ring includes a focusing ring provided at an inner side portion and a lower portion thereof.

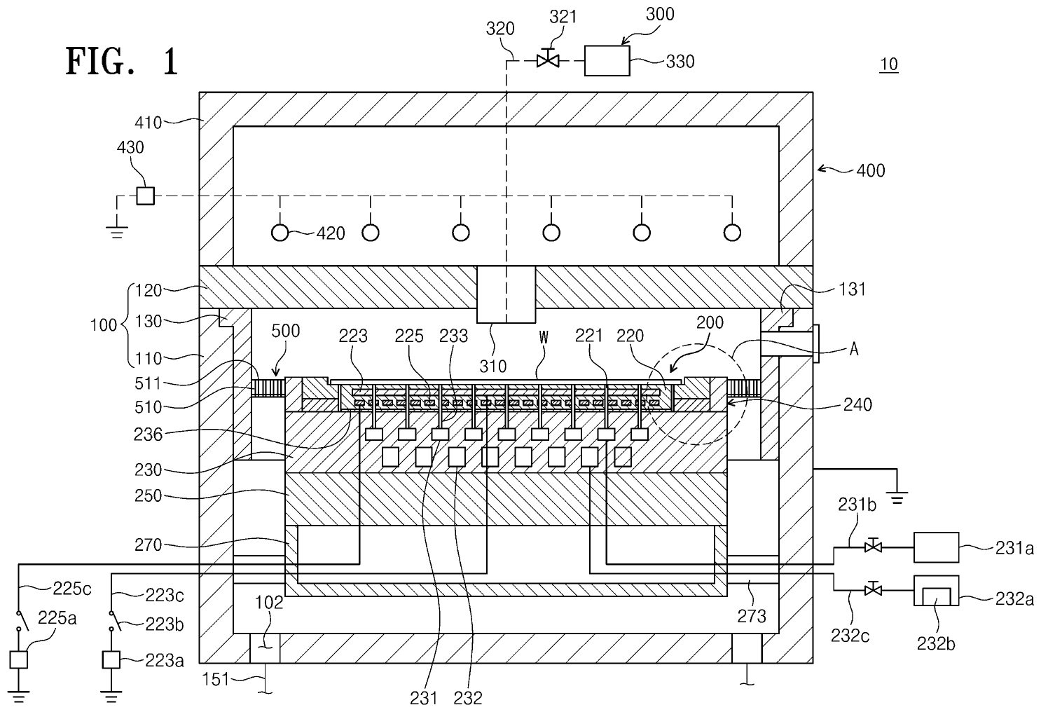

FIG. 1 is a cross-sectional view illustrating a substrate treating apparatus according to an embodiment of the inventive concept. Referring to FIG. 1, a substrate treating apparatus 10 treats a substrate “W” by using plasma. For example, the substrate treating apparatus 10 may perform an etching process on the substrate “W”. In the embodiment of the inventive concept, a substrate treating apparatus for etching a substrate by using plasma will be described. However, the inventive concept is not limited thereto, and may be applied to various kinds of apparatuses that perform processes by supplying plasma to chambers.

The substrate treating apparatus 10 may include a process chamber 100, a support unit 200, a gas supply unit 300, a plasma source 400, and an exhaustion unit 500.

The process chamber 100 has a treatment space in which a substrate is treated in the interior thereof. The process chamber 100 includes a housing 110, a cover 120, and a liner 130.

The housing 110 has an open-topped space in the interior thereof. The interior space of the housing 110 is provided as a treatment space in which a substrate treating process is performed. The housing 110 is formed of a metallic material. The housing 110 may be formed of aluminum. The housing 110 may be grounded. An exhaust hole 102 is formed on a bottom surface of the housing 110. The exhaust hole 102 is connected to an exhaust line 151. The reaction side-products generated in the process and gases left in the interior space of the housing 110 may be discharged to the outside through the exhaust line 151. Through the exhaustion process, the pressure of the interior of the housing 110 is reduced to a specific pressure.

The cover 120 covers an opened upper surface of the housing 110. The cover 120 has a plate shape, and the interior space of the housing 110 is closed. The cover 120 may include a dielectric window.

The liner 130 is provided in the interior of the housing 110. The liner 130 has an interior space, an upper surface and a lower surface of which are opened. The liner 130 may have a cylindrical shape. The liner 130 may have a radius corresponding to an inner surface of the housing 110. The liner 130 is provided along the inner surface of the housing 110.

A support ring 131 may be formed at an upper portion of the liner 130. The support ring 131 is a ring-shaped plate, and protrudes to the outside of the liner 130 along the circumference of the liner 130. The support ring 131 is positioned at an upper end of the housing 110, and supports the liner 130. The liner 130 may be formed of the same material as the housing 110. The liner 130 may be formed of aluminum. The liner 130 protects the inner surface of the housing 110. For example, in a process of exciting a process gas, arc discharging is generated in the interior of the process chamber 100. The arc discharging damages peripheral devices. The liner 130 may prevent an inner surface of the housing 110 from being damaged due to arc discharging by protecting the inner surface of the housing 110. Further, the reaction side-products generated in the substrate treating process are prevented from being deposited on the inner wall of the housing 110. The liner 130 is inexpensive and may be easily exchanged as compared with the housing 110. Accordingly, when the liner 130 is damaged due to arc discharging, the operator may exchange the liner 130 with anew liner 130.

The support unit 200 supports the substrate in the treatment space in the interior of the process chamber 100. For example, the support unit 200 is disposed in the interior of the housing 110. The support unit 200 supports the substrate “W”. The support unit 200 may be provided in an electrostatic chuck scheme of suctioning the substrate “W” by using an electrostatic force. Unlike this, the support unit 200 may support the substrate “W” in various methods such as mechanical clamping. Hereinafter, the support unit 200 provided in an electrostatic chuck scheme will be described.

The support unit 200 includes a support plate 220, an electrostatic electrode 223, a passage forming plate 230, an edge ring assembly 240, an insulation plate 250, and a lower cover 270. The support unit 200 may be located in the interior of the process chamber 100 to be spaced upwards apart from the bottom surface of the chamber housing 110. The support plate 220 is located at an upper end of the support unit 200. The support plate 220 may be formed of a dielectric substance of a disk shape. The substrate “W” is positioned on the upper surface of the support plate 220. A first supply passage 221 that is used as a passage, through which a heat transfer gas is supplied to a bottom surface of the substrate “W”, is formed in the support plate 220.

The electrostatic electrode 223 is buried in the support plate 220. The electrostatic electrode 223 is electrically connected to a first lower power source 223a. An electrostatic force may be applied between the electrostatic electrode 223 and the substrate “W” by a current applied to the electrostatic electrode 223, and the substrate “W” may be suctioned to the support plate 220 by the electrostatic force.

The passage forming plate 230 is located at a lower portion of the support plate 220. A bottom surface of the support plate 220 and an upper surface of the passage forming plate 230 may be bonded to each other by an adhesive 236. The passage forming plate 230 has a first circulation passage 231, a second circulation passage 232, and a second supply passage 233. The first circulation passage 231 is provided as a passage, through which the heat transfer gas circulates. The second circulation passage 232 is provided as a passage, through which a cooling fluid circulates. The second supply passage 233 connects the first circulation passage 231 and the first supply passage 221. The first circulation passage 231 may be formed in the interior of the passage forming plate 230 to have a spiral shape. Furthermore, the first circulation passages 231 may be disposed such that passages having ring shapes of different radii have the same center. The first circulation passages 231 may communicate with each other. The first circulation passages 231 are formed at the same height.

The first circulation passages 231 are connected to a heat transfer medium storage 231a through a heat transfer medium supply line 231b. A heat transfer medium is stored in the heat transfer medium storage 231a. The heat transfer medium includes an inert gas. The heat transfer medium may include a helium (He) gas. The helium gas is supplied to the first circulation passages 231 through the supply line 231b, and is supplied to the bottom surface of the substrate “W” after sequentially passing through second supply passages 233 and the first supply passages 221. The helium gas functions as a medium that helps exchange of heat between the substrate “W” and the support plate 220. Accordingly, the temperature of the substrate “W” is uniform as a whole.

The second circulation passages 232 are connected to a cooling fluid storage 232a through a cooling fluid supply line 232c. The cooling fluid storage 232a may store a cooling fluid. A cooler 232b may be provided in the cooling fluid storage 232a. The cooler 232b cools the cooling fluid to a specific temperature. Unlike this, the cooler 232b may be installed on the cooling fluid supply line 232c. The cooling fluid supplied to the second circulation passages 232 through the cooling fluid supply line 232c cools the passage forming plate 230 while circulating along the second circulation passages 232. The passage forming plate 230 may cool the support plate 220 and the substrate “W” together while being cooled to maintain the substrate “W” at a specific temperature. For the above-mentioned reasons, temperatures of lower portions of the support plate 220 and the edge ring assembly 240 are generally lower than temperatures of upper portions thereof.

The edge ring assembly 240 is disposed at an edge area of the support unit 200. The edge ring assembly 240 has a ring shape, and is configured to surround the support plate 220 and the substrate supported on the support plate 220. For example, the edge ring assembly 240 is disposed along a circumference of the support plate 220 to support an outer area of the substrate “W”. The edge ring assembly 240 allows plasma in the process chamber 100 to be concentrated in an area that faces the substrate “W”.

The insulation plate 250 is located at a lower portion of the passage forming plate 230. The insulation plate 250 is formed of an insulating material, and electrically insulates the passage forming plate 230 and the lower cover 270.

The lower cover 270 is located at a lower end of the support unit 200. The lower cover 270 is spaced upwards apart from the bottom surface of the housing 110. An open-topped space is formed in the interior of the lower cover 270. The upper surface of the lower cover 270 is covered by the insulation plate 250. Accordingly, the outer radius of the section of the lower cover 270 is the same as the outer radius of the insulation plate 250. A lift pin module (not illustrated) that receives the transferred substrate “W” from a transfer member on the outside to the electrostatic chuck and positions the substrate “W” on the support plate may be located in the interior space of the lower cover 270.

The lower cover 270 has a connecting member 273. The connecting member 273 connects an outer surface of the lower cover 270 and an inner wall of the housing 110. A plurality of connecting members 273 may be provided on an outer surface of the lower cover 270 at a specific interval. The connecting members 273 support the support unit 200 in the interior of the process chamber 100. Further, the connecting members 273 are connected to an inner wall of the housing 110 such that the lower cover 270 is electrically grounded.

A first power line 223c connected to the first lower power source 223a, the heat transfer medium supply line 231b connected to the heat transfer medium storage 231a, and the cooling fluid supply line 232c connected to the cooling fluid storage 232a may extend into the lower cover 270 through the interior space of the connecting member 273.

The gas supply unit 300 supplies a gas into the treatment space in the interior of the process chamber 100. The gas supplied by the gas supply unit 300 includes a process gas used for treatment of the substrate. Furthermore, the gas supplied by the gas supply unit 300 may include a cleaning gas used to clean an inside of the process chamber 100.

The gas supply unit 300 includes a gas supply nozzle 310, a gas supply line 320, and a gas storage unit 330. The gas supply nozzle 310 is installed at a central portion of the cover 120. An ejection hole is formed on the bottom surface of the gas supply nozzle 310. The ejection hole is located below the cover 120, and supplies the gas into the interior of the process chamber 100. The gas supply line 320 connects the gas supply nozzle 310 and the gas storage unit 330. The gas supply line 320 supplies the gas stored in the gas storage unit 330 to the gas supply nozzle 310. A valve 321 is installed in the gas supply line 320. The valve 321 opens and closes the gas supply line 320, and adjusts a flow rate of the gas supplied through the gas supply line 320.

The plasma source 400 generates plasma from the gas supplied into the treatment space in the interior of the process chamber 100. The plasma source 400 is provided outside the treatment space of the process chamber 100. According to an embodiment, an inductively coupled plasma (ICP) source may be used as the plasma source 400. The plasma source 400 includes an antenna seal 410, an antenna 420, and a radio frequency (RF) power source 430.

The antenna seal 410 has an open-bottomed cylindrical shape. The antenna seal 410 has a space in the interior thereof. The antenna seal 410 has a diameter corresponding to the process chamber 100. A lower end of the antenna seal 410 may be detachably provided in the cover 120. The antenna 420 is disposed in the interior of the antenna seal 410. The antenna 420 is a spiral coil that is wound a plurality of times, and is connected to the RF power source 430. The antenna 420 is supplied with electric power from the RF power source 430. The RF power source 430 may be located outside the process chamber 100. The antenna 420, to which electric power has been applied, may form an electromagnetic field in the treatment space of the process chamber 100. The process gas is excited into a plasma state by an electromagnetic field.

The exhaustion unit 500 is located between an inner wall of the housing 110 and the support unit 200. The exhaustion unit 500 includes an exhaustion plate 510 having a through-hole 511. The exhaustion plate 510 has an annular ring shape. The exhaustion plate 510 has a plurality of through-holes 511. The process gas provided into the housing 110 passes through through-holes 511 of the exhaustion plate 510 and is exhausted through the exhaust hole 102. The flow of the process gas may be controlled according to the shape of the exhaustion plate 510 and the shape of the through-hole 511.

A heater is buried in the support plate 220. A heater 225 is located under the electrostatic electrode 223. The heater 225 generates heat by resisting against a heat emitting power source (current) applied by a heater cable 225c. The generated heat is transferred to the substrate “W” through the support plate 220. The substrate “W” is maintained at a specific temperature by the heat generated by the heater 225.

A heater power source supply unit 225a is provided to apply a heating power source to the heater 225. A filter unit (illustration omitted) for interrupting high-frequency waves from being introduced into the heater power source supply unit 225a may be provided between the heater power source supply unit 225a and the heater 225. As an example, when a high-frequency power source of 13.5 MHz is applied by the plasma source 400 to generate plasma, it may be designed to, for example, cause the heat emitting power source that is an AC power source of 60 Hz to pass through the heater cable 225c and prevent an RF of 13.56 MHz from being introduced into the heater power source supply unit 225a. The filter unit may be provided with elements, such as a capacitor, an inductor, and the like.

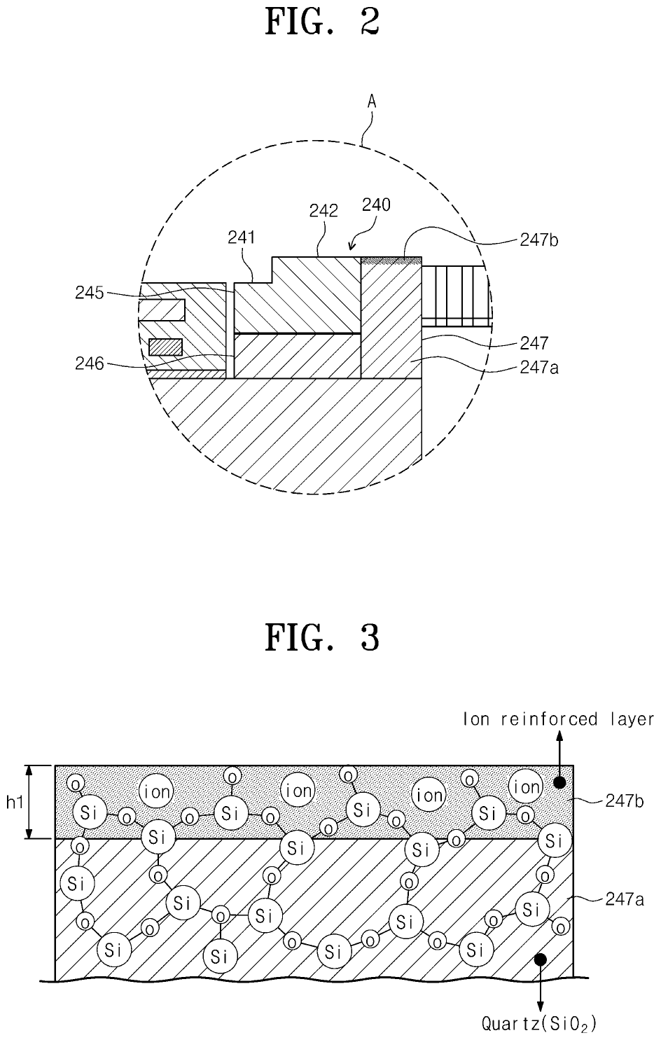

Hereinafter, the edge ring assembly 240 of the substrate treating apparatus according to the embodiment of the inventive concept will be described. FIG. 2 is an enlarged view of portion “A” of FIG. 1, and is a cross-sectional view of an edge ring assembly that constitutes the substrate treating apparatus according to the embodiment of the inventive concept. The embodiment of the inventive concept will be described with reference to FIGS. 1 and 2.

The edge ring assembly 240 may include a focusing ring 245, an insulation ring 246, and a cover ring 247. The outer surface of the support plate 220 and the inner surface of the focusing ring 245 may be spaced apart from each other by a preset distance. The focusing ring 245 adjusts a sheath and a plasma interface.

The focusing ring 245 is formed of a conductive material. The focusing ring 245 may include silicon (Si), silicon carbide (SiC), and the like. A first layer 241 and a second layer 242 may be formed on an upper surface of the focusing ring 245. The first layer 241 and the second layer 242 may be classified with reference to a height of the focusing ring 245. An upper surface of the first layer 241 is exposed in an inner area of the focusing ring 245. The first layer 241 may be provided at a height corresponding to the upper surface of the support plate 220, and may support an outer area of the substrate “W”. As an example, the first layer 241 may be provided at a height that is the same as the upper surface of the support plate 220, and may contact a lower surface of an outer side of the substrate “W”. Furthermore, the first layer 241 may be provided to be lower than the upper surface of the support plate 220 by a preset size, and a preset gap may be formed between the lower surface of the outer side of the substrate and the first layer 241. The first layer 241 may have a flat surface that is parallel to the lower surface of the substrate “W”. The second layer 242 may be formed to be higher than the first layer 241, and may protrude from an outer end of the first layer 241 upwards. According to an embodiment, the height of the second layer 242 may be at least the same as or higher than an upper surface of the substrate “W” loaded on the support plate 220. Due to the height difference of the first layer 241 and the second layer 242, the sheath, the plasma interface, and an electric field are adjusted so that the plasma may be guided to be concentrated on the substrate “W”.

The insulation ring 246 may be provided below the focusing ring 245. The insulation ring 246 electrically insulates the passage forming plate 230 and the focusing ring 245. The insulation ring 246 may include a dielectric material, for example, quartz, ceramic, an yttrium oxide (Y₂O₃), alumina (Al₂O₃), or a polymer. Meanwhile, the insulation ring 246 may be omitted, and the focusing ring 245 may be located to directly contact the passage forming plate 230.

In the embodiment, the cover ring 247 may be located on an outward direction of the focusing ring 245. The cover ring 247 may have a ring shape to surround an outer area of the focusing ring 245. The cover ring 247 prevents a side surface of the focusing ring 245 from being directly exposed to plasma or plasma from being introduced into a side of the focusing ring 245.

The cover ring 247 includes a quartz material, a surface of which is ion-reinforced to improve an anti-corrosion property (anti-plasma property). A reinforced surface layer 247b of the cover ring 247 is ion-reinforced to improve an anti-corrosion property (anti-plasma property). FIG. 3 schematically illustrates a bonding structure of molecules between the reinforced surface layer 247b and a material layer 247a of the cover ring 247 of FIG. 2.

Referring to FIG. 3, the cover ring 247 may include the material layer 247a, a main substance of which is quartz (SiO₂), and the ion-reinforced reinforced surface layer 247b having a thickness hi of 10 μm to 500 μm. The material layer 247a, the main substance of which is quartz (SiO₂), may be formed of amorphous glass quartz. The reinforced surface layer 247b is formed by injecting a network modifier at an empty site formed between the network structures due to bonding of molecules formed by the quartz (SiO₂). For example, the network modifier selects ions of Na⁺, K⁺, Ca²⁺, or Mg²⁺ as surface reinforcing ions, and injects the ions into the empty site of the network structure according to bonding of the molecules formed by quartz (SiO₂). Among the network modifiers, a radius of Na⁺, K⁺, Ca²⁺, or Mg²⁺ are larger than that of Si⁴⁺. The radii of the ions are slightly different according to papers and measurement conditions, but the radii of the network modifiers are larger than that of Si⁴⁺ in consideration of the effective ion radii of R. D. Shannon (1976). “Revised effective ionic radii and systematic studies of interatomic distances in halides and chalcogenides”, the ionic radius of Na⁺ is 102 μm, the ionic radius of K+ is 138 μm, the ionic radius of Ca²⁺ is 100 μm, the ionic radius of Ng²⁺ is 72 μm, and the ionic radius of Si⁴⁺ is 40 μm. A compression stress is generated around a network structure on a surface of the cover ring 247, in which the reinforced surface layer 247b is formed by injecting the network modifier according to the embodiment of the inventive concept so that a mechanical strength and an anti-corrosion property of the quartz material increase. As the cover ring 247 has an excellent mechanical strength and an excellent anti-corrosion property, an exchange period of the cover ring 247 may be improved.

In the conventional ion reinforcement, a technology of exchanging ions of a surface that constitutes a material layer (for example, a quartz material layer) by ions of large radii has been discussed. For example, this is a technology of including aluminum (Al) or yttrium (Y) powder in the quartz material powder to exchange ions of quartz, in sintering quartz. Because the technology requires a high fusion temperature, production performance decreases and costs increase, mold manufacturing and maintaining costs that are necessary for high-temperature fusion are added, uniform dispersing of a multi-component system becomes difficult due to high viscosity during fusion, and production performance is low as machining residuals are left due to the necessity of additional machining according to the shape thereof.

However, the surface of the quartz member (the cove ring in the embodiment) according to the embodiments of the inventive concept may be reinforced at a low-temperature environment, and the exchange period of the quartz member having the reinforced surface may be improved as the anti-corrosion property is improved. Furthermore, the cover ring 247 having the reinforced surface, which is manufactured according to the embodiment of the inventive concept may protect the focusing ring 245 and the insulation ring 246 located at a lower end of the cover ring 247 from being exposed to plasma.

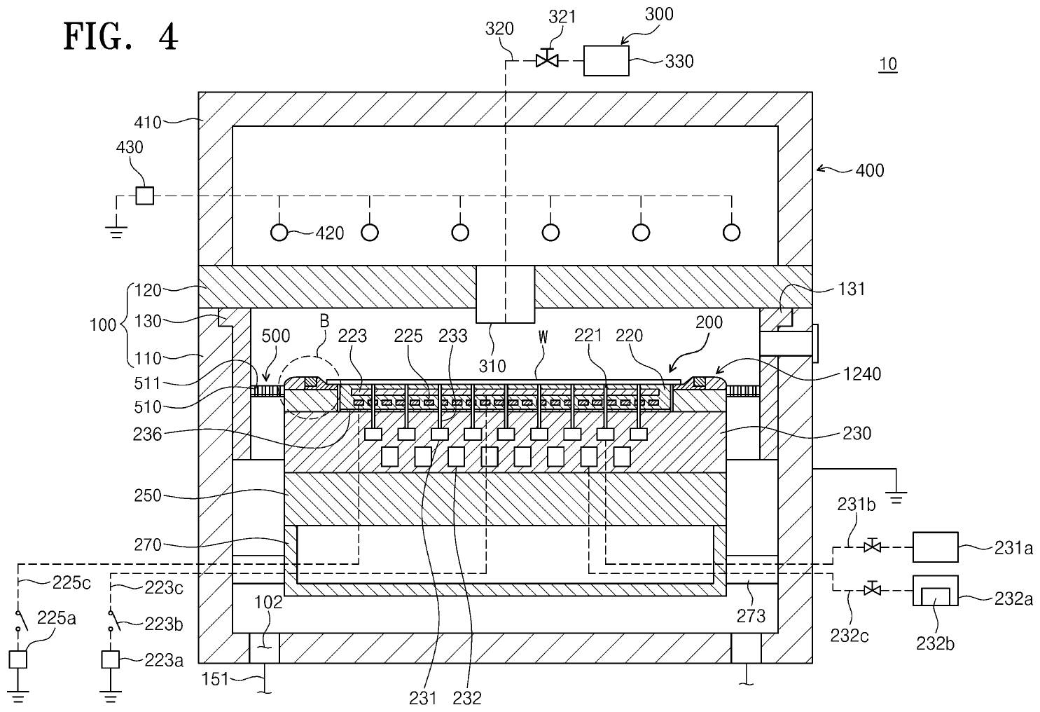

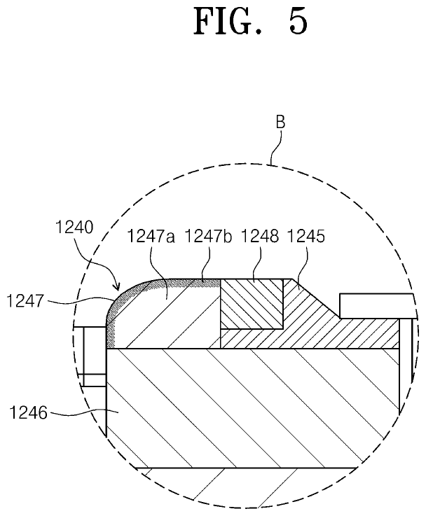

Furthermore, because the quartz member (according to the embodiment, the cover ring) according to the embodiments of the inventive concept has a very high sublimation point, for example, a sublimation point of CaF₂ of 1,418° C., a sublimation point of NaF of 1,695° C., a sublimation point of KF of 1,502° C., and a sublimation point of MgF₂ of 2,260° C., as compared with a sublimation point of SiO4 of 1,418° C., when being exposed to a plasma environment including fluorine (“F”), it is not sublimated even during a plasma reaction and is applied to a surface constituting component of the quartz material so that etching by an F radical may be prevented. FIG. 4 is a view illustrating a substrate treating apparatus according to another embodiment of the inventive concept. FIG. 5 is an enlarged view of portion “B” of FIG. 4, and is a cross-sectional view of an edge ring assembly that constitutes the substrate treating apparatus according to another embodiment of the inventive concept. An edge ring assembly 1240 according to another embodiment of the inventive concept will be described with reference to FIGS. 4 and 5.

The edge ring assembly 1240 includes a focusing ring 1245, an insulation ring 1246, an inner cover ring 1248, and an outer cover ring 1247.

The focusing ring 1245 is positioned on the insulation ring 1246. The inner cover ring 1248 is positioned on an outer upper surface of the focusing ring 1245, and protects the outer upper surface of the focusing ring 1245. The outer cover ring 1247 is provided on an outer side of the focusing ring 1245 and the inner cover ring 1248.

The focusing ring 1245 is formed of a conductive material. The focusing ring 1245 may include silicon (Si), silicon carbide (SiC), and the like. An upper surface of the focusing ring 1245 may be formed at different heights. An inner area of the focusing ring 1245 may be provided at a height corresponding to the upper surface of the support plate 220, and may support an outer area of the substrate “W”. As an example, the inner area of the focusing ring 1245 may be provided at a height that is the same as the upper surface of the support plate 220, and may contact a lower surface of an outer side of the substrate “W”. Furthermore, the inner area of the focusing ring 1245 may be provided to be lower than the upper surface of the support plate 220 by a preset size, and a preset gap may be formed between an outer lower surface of the substrate “W” and the inner area of the focusing ring 1245. The focusing ring 1245 may protrude upwards as it goes from the inner area toward the outer area thereof. According to an embodiment, the focusing ring 1245 may include a part that is inclined from the inner area toward the outer area to protrude further than the inner area. Due to the height difference of the inner area of the focusing ring 1245 and the protruding part, the sheath, the plasma interface, and an electric field are adjusted so that the plasma may be guide to be concentrated on the substrate “W”. The outer area of the focusing ring 1245 may be recessed by a height of the inner cover ring 1248 so that the inner cover ring 1248 may be positioned on the outer area of the focusing ring 1245.

The inner cover ring 1248 may protect an outer upper portion of the focusing ring 1245. A part of the inner cover ring 1248 that contacts the focusing ring 1245 may include an amorphous anti-plasma high-silica material containing amorphous SiO₂ of 96.0 to 99.5 wt % and containing Al₂O₃ of 0.5 to 4.0 wt %. In the embodiment, the inner cover ring 1248 may have a permittivity that is higher than that of the outer cover ring 1247. The inner cover ring 1248 may have a first permittivity that is lower than that of the focusing ring 1245.

A main substance of the inner cover ring 1248 is amorphous SiO₂ and contains anti-corrosion Al₂O₃ of 0.5 to 4.0 wt % so that glass material characteristics having amorphous characteristics and an excellent anti-plasma resistance may be implemented. The amorphous glass material is not selectively corroded due to absence of grain boundaries, and thus has an excellent anti-corrosion property in a plasma etching environment and may decrease particles generated during a process. When the inner cover ring 1248 contains the amorphous SiO₂ of 96.0 to 99.5 wt %, the anti-etching property may be remarkably improved during the plasma etching process by uniformly distributing the anti-corrosion Al₂O₃ (0.5 to 4.0 wt %) while similar substances such as quartz are shown. When the high-silica amorphous glass material of 96.0 to 99.5 wt % is used, the process may be prevented from being badly influenced due to an SiF₄ reactant evaporated at a low temperature, and the life span of the chamber and the exchange period of the facility may be improved due to improvement of the anti-plasma characteristics.

The outer cover ring 1247 includes a quartz material, a surface of which is ion-reinforced to improve an anti-corrosion property (anti-plasma property). A reinforced surface layer 1247b of the outer cover ring 1247 is ion-reinforced to improve an anti-corrosion property (anti-plasma property). The bonding structure of molecules between the reinforced surface layer 1247b and a material layer 1247a of the outer cover ring 1247 is the same as that of the embodiment of FIG. 3, and thus is replaced by the description of the embodiment illustrated in FIG. 3.

The outer peripheral part of the outer cover ring 1247 may be curved to prevent electric discharges between the outer cover ring 1247 and other subsidiary components. That is, an upper surface and an outer wall of the outer cover ring 1247 may be curved such that a cross-section of the outer cover ring 1247 has a curved fan shape.

Although the cover ring of the same material as that of the inner cover ring 1248 has a high anti-corrosion property whereas, due to a high viscosity generated when the high-silica amorphous glass of 96.0 to 99.5 wt % and Al₂O₃ of 0.5 to 4.0 wt % are mixed and fused, it is difficult to uniform disperse (mix) them when the cover ring is manufactured, uniform dispersing may be achieved as restrictions in the size and the shape may be reduced when the cover ring is provided inside the outer cover ring 1247 and is positioned on the focusing ring 1245 as in the embodiment of the inventive concept.

Because the outer cover ring 1247 and the substrate “W” are spaced apart from each other due to the inner cover ring 1248, a possibility of the substrate “W” being badly influenced by the network modifier, such as Na, Ca, K, or Mg, which may be etched in the outer cover ring 1247 may be prevented.

The insulation ring 1246 may be provided below the focusing ring 1245. The insulation ring 1246 electrically insulates the passage forming plate 230 and the focusing ring 1245. The insulation ring 1246 may include a dielectric material, for example, quartz, ceramic, an yttrium oxide (Y₂O₃), alumina (Al₂O₃), or a polymer. Meanwhile, the insulation ring 1246 may be omitted, and the focusing ring 1245 may be located to directly contact the passage forming plate 230.

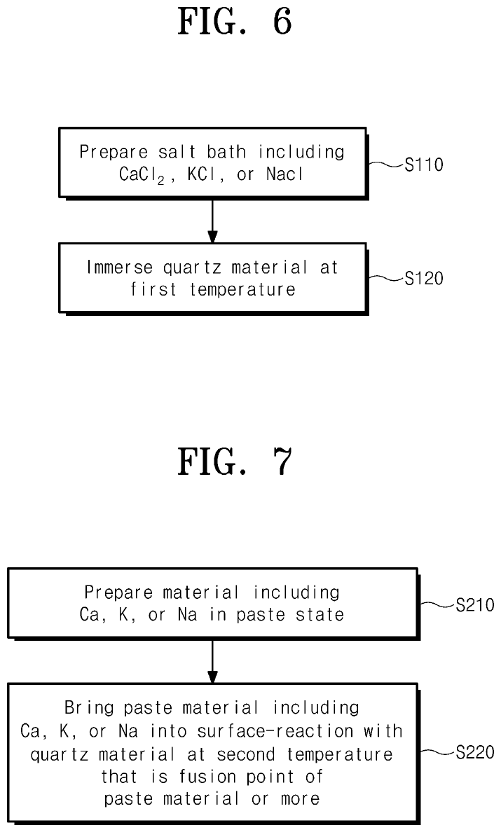

FIG. 6 is a flowchart illustrating a wetting type ion reinforcing method using a quartz material according to an embodiment of the inventive concept; and a method of manufacturing a quartz material according to the embodiment of the inventive concept will be illustrated with reference to FIG. 6. According to the embodiment, a salt bath including CaCl₂), KCl, NaCl, or MgCl₂ is prepared (S110). A machined quartz material (for example, a quartz material machined for the cover ring) is immersed in the prepared salt bath in a first temperature condition. The first temperature may be a room temperature. In another embodiment, the first temperature may be a temperature that is higher than a room temperature. Because CaCl₂), KCl, NaCl, or MgCl₂ are soluble, the network modifier such as Ca²⁺, K⁺, Na^{m}, or Mg²⁺ is present in a state of ions in water, and the network modifier that is present in the state of ions reacts with a surface of the quartz material to penetrate into the network structure of the quartz material and reinforce the surface of the quartz material. A period of time for the immersion in the salt bath is a period of time, for which the network modifier penetrates into the network structure of the quartz material by a thickness of 10 μm to 500 μm. According to the method for manufacturing a quartz material according to the embodiment referenced through FIG. 6, the surface of the quartz material may be reinforced in a condition of a room temperature, so that production costs may be reduced due to absence of a high-temperature condition and uniform reinforcing of a surface may be possible for a wide area, as compared with a case, in which fusion at a high temperature of 2000° C. or more is necessary to mix Al or Y with quartz.

FIG. 7 is a flowchart illustrating a drying type ion reinforcing method using a quartz material according to another embodiment of the inventive concept. A method of manufacturing a quartz material according to the embodiment of the inventive concept will be illustrated with reference to FIG. 7. According to the embodiment, a material containing a network modifier such as Ca²⁺, K⁺, Na⁺, or Mg²⁺ is prepared in a paste state (S210). As an example, the paste material including Ca²⁺, K⁺, Na⁺, or Mg²⁺ may be CaCl₂), KCl, NaCl, or MgCl₂. The prepared paste material is brought into reaction with a surface of a quartz material (for example, a quartz material machined for the cover ring) at a second temperature that is a fusion point of the paste material or more. According to the embodiment, the network modifier is injected into an empty site of the network structure by depositing the prepared paste material on the surface of the machined quartz material (for example, the quartz material machine for the cover ring) and heating the paste material at the fusion point or more. Exemplarily, because the fusion point of CaCl₂) is 772° C., the fusion point of KCl is 770° C., the fusion point of NaCl is 801° C., and the fusion point of MgCl₂ is 714° C., the second temperature may be set to about 700 to 850° C. A period of time for the surface reaction is a period of time, for which the network modifier penetrates into the network structure of the quartz material by a thickness of 10 μm to 500 μm. According to the method for manufacturing a quartz material according to the embodiment referenced through FIG. 7, the surface of the quartz material may be reinforced in a condition of a temperature ranging from 700 to 850° C., so that production costs may be reduced due to absence of a high-temperature condition and uniform reinforcing of a surface may be possible for a wide area, as compared with a case, in which fusion at a high temperature of 2000° C. or more is necessary to mix Al or Y with quartz.

According to the cover ring provided for the edge ring assembly and the substrate treating apparatus including the same according to the embodiment of the inventive concept, the substrate may be uniformly treated, and plasma may be distributed such that a substrate treating efficiency may be increased.

The cover ring provided for the edge ring assembly according to the embodiment of the inventive concept has a high anti-plasma property, hardly causes particles, and increases a component exchange period.

According to the method for manufacturing a quartz component having an improved plasma property, which is exposed to plasma including fluorine, production costs may be reduced as it is manufactured in a relatively low temperature condition.

A cover ring provided for the edge ring assembly according to the embodiment of the inventive concept may be uniformly reinforced for a wide surface area.

The effects of the inventive concept are not limited to the above-described ones. Unmentioned effects will be clearly understood from the specification and the accompanying drawings by those skilled in the art to which the inventive concept pertains.

The above detailed description exemplifies the inventive concept. Furthermore, the above-mentioned contents describe the exemplary embodiment of the inventive concept, and the inventive concept may be used in various other combinations, changes, and environments. That is, the inventive concept can be modified and corrected without departing from the scope of the inventive concept that is disclosed in the specification, the equivalent scope to the written disclosures, and/or the technical or knowledge range of those skilled in the art. The written embodiment describes the best state for implementing the technical spirit of the inventive concept, and various changes required in the detailed application fields and purposes of the inventive concept can be made. Accordingly, the detailed description of the inventive concept is not intended to restrict the inventive concept in the disclosed embodiment state. Furthermore, it should be construed that the attached claims include other embodiments.

What is claimed is:

1. A substrate treating apparatus comprising:
a process chamber configured to provide a treatment space in an interior thereof;
a support unit configured to support a substrate in the treatment space;
a gas supply unit configured to supply a process gas into the treatment space; and
a plasma source configured to generate plasma from the process gas,
wherein the support unit includes:
a support plate, on which the substrate is positioned; and
an edge ring assembly configured to surround the substrate supported on the support plate, and configured to form the plasma in the substrate, and
wherein the edge ring assembly includes:
a focusing ring formed of a first material, and configured to form distribution of the plasma in the substrate; and
a cover ring provided in an area of the substrate, which is on an outer side of the focusing ring, formed of a second material having a network structure, and including a reinforced surface layer provided by injecting a network modifier into an empty site of the network structure.

2. The substrate treating apparatus of claim 1, wherein the first material is a conductive material, and
wherein the second material is a material having an insulating performance that is higher than that of the first material.

3. The substrate treating apparatus of claim 1, wherein the first material is silicon carbide (SiC), and
wherein the second material is quartz having an amorphous network structure.

4. The substrate treating apparatus of claim 1, wherein an ion radius of the network modifier is larger than that of Si⁴⁺.

5. The substrate treating apparatus of claim 1, wherein the network modifier is any one or more of Na⁺, K⁺, Ca²⁺, or Mg²⁺.

6. The substrate treating apparatus of claim 1, wherein the reinforced surface layer has a thickness of 10 μm to 500 μm.

7. The substrate treating apparatus of claim 1, wherein the edge ring assembly further includes:
an inner cover ring provided between the cover ring and the focusing ring, and located above an outer area of the focusing ring, and
wherein the inner cover ring is formed of a third material, in which SiO₂ and Al₂O₃ are mixed at a first ratio.

8. The substrate treating apparatus of claim 7, wherein the inner cover ring includes 96.0 to 99.5 wt % of SiO₂ and 0.5 to 4.0 wt % of Al₂O₃.

9. The substrate treating apparatus of claim 1, wherein the process gas is a gas containing fluorine.

10. A cover ring of an edge ring assembly configured to surround a substrate and form plasma in the substrate in an apparatus for treating the substrate by the plasma, the cover ring comprising:
a reinforced surface layer having an inner diameter that is larger than a diameter of the substrate to be spaced apart from the substrate by a specific distance, formed of a material including a network structure, and provided by injecting a network modifier into an empty site of the network structure.

11. The cover ring of claim 10, wherein a material of the cover ring is quartz having an amorphous network structure.

12. The cover ring of claim 10, wherein an ion radius of the network modifier is larger than that of Si⁴⁺.

13. The cover ring of claim 10, wherein the network modifier is any one or more of Na⁺, K⁺, Ca²⁺, or Mg²⁺.

14. The cover ring of claim 10, wherein the reinforced surface layer has a thickness of 10 μm to 500 μm.

15. The cover ring of claim 10, wherein a process gas for forming the plasma is a gas containing fluorine, and the reinforced surface layer is exposed to fluorine radicals excited from the process gas.
